(19) United States
(12) Patent Application Publication
(10) Pub. No.: US 2025/0073847 A1
(43) Pub. Date: Mar. 6, 2025

(54) FILM THICKNESS SIGNAL PROCESSING APPARATUS, POLISHING APPARATUS, AND FILM THICKNESS SIGNAL PROCESSING METHOD

(71) Applicant: EBARA CORPORATION, Tokyo (JP)

(72) Inventors: Keita YAGI, Tokyo (JP); Yoichi SHIOKAWA, Tokyo (JP); Yuta SUZUKI, Tokyo (JP)

(21) Appl. No.: 18/816,123

(22) Filed: Aug. 27, 2024

(30) Foreign Application Priority Data
Aug. 31, 2023 (JP) 2023-140929

(51) Int. Cl. B24B 49/02; B24B 49/10; G01B 7/06

(52) U.S. Cl. CPC B24B 49/02; B24B 49/105; G01B 7/10

(57) ABSTRACT

Provided is a film thickness signal processing apparatus that improves in accuracy of a film-thickness distribution within a measurement range. The film thickness signal processing apparatus includes a receiver and a corrector. The receiver receives sensor data output from an eddy current sensor and generates first film thickness data 168 and second film thickness data 172. The corrector corrects the first film thickness data 168 and the second film thickness data 172 generated by the receiver. The corrector obtains corrected film thickness data 166 based on a size of the measurement range 174, 176 on the polishing object as a measurement target in a single measurement by the eddy current sensor, the first film thickness data 168 measured at a first measurement point 146 on the polishing object, and the second film thickness data 172 measured at a second measurement point 148 on the polishing object. A distance between the first measurement point 146 and the second measurement point 148 is equal to or less than the size of the measurement range 174, 176.

### TECHNICAL FIELD

This invention relates to a film thickness signal processing apparatus, a polishing apparatus, and a film thickness signal processing method. This application claims priority from Japanese Patent Application No. 2023-140929, filed on Aug. 31, 2023. The entire disclosure including the descriptions, the claims, the drawings, and the abstracts in Japanese Patent Application No. 2023-140929 is herein incorporated by reference.

### BACKGROUND ART

In recent years, as semiconductor devices have become more highly integrated and dense, the wiring of circuits has become increasingly fine, and the number of layers in multilayer wiring has increased. In order to achieve multilayer wiring while also making circuits finer, it is necessary to precisely flatten the surface of the semiconductor devices.

Chemical mechanical polishing (CMP) is a well-known technology for planarizing surfaces of semiconductor devices. A polishing apparatus for performing CMP includes a polishing table with a polishing pad attached, and a top ring (holder) for holding a polishing object (for example, a substrate such as a semiconductor wafer, or various films formed on a surface of a substrate). The polishing apparatus polishes a polishing object by pressing the polishing object held in the top ring against the polishing pad while rotating a polishing table with a motor (driver) that can rotatably drive the polishing table.

The polishing apparatus includes a film thickness measurement device for an endpoint detection of a polishing process based on a film thickness of the polishing object. The film thickness measurement device includes a film thickness sensor to detect the film thickness of the polishing object. The film thickness sensor is typically an eddy current sensor or an optical sensor.

The eddy current sensor or optical sensor is arranged in a hole formed in the polishing table, and as it rotates with the polishing table, it detects the film thickness when it is opposed to the polishing object. The eddy current sensor induces eddy currents in the polishing object, such as a conductive film, and detects changes in the thickness of the polishing object by measuring changes in the magnetic field generated by the induced eddy currents. On the other hand, the optical sensor detects the thickness of the polishing object by irradiating light onto the polishing object and measuring an interference wave reflected from the polishing object.

The film-thickness distribution measured by the film thickness sensor is a mapping of the measured film thickness values (film thickness data) based on the detected signals from the entire measurement spots of the sensor (in the case of the eddy current sensor, the measurement range is on the wafer where the eddy currents induced in the wafer are present. In the case of the optical sensor, the measurement range is an area of light irradiation on the wafer. Hereafter, this is referred to as a “measurement range.”) to the positions of the measurement points on the wafer. For example, the position of the measurement point may be the position of the center of the sensor. While the measurement range is present as a range on the wafer, the measurement value can be mapped to the position of the measurement point, which is a specific position on the wafer. For this reason, there is room for improvement in the accuracy of the film-thickness distribution within the measurement range, or in other words, the spatial resolution.

### CITATION LIST

### Patent Literature

PTL 1: Japanese Patent No. 6795337

### SUMMARY OF INVENTION

### Technical Problem

One embodiment of the present invention was made to solve such problems, and its objective is to provide a film thickness signal processing apparatus that improves the accuracy of the film-thickness distribution within the measurement range.

### Solution to Problem

To solve the above-described problem, in a first embodiment, a film thickness signal processing apparatus includes a receiver and a corrector. The receiver is configured to receive sensor data output from a film thickness sensor to detect a film thickness of a polishing object and generate first film thickness data and second film thickness data. The corrector is configured to correct the first and second film thickness data generated by the receiver. The corrector obtains corrected film thickness data based on a size of a measurement range on the polishing object as a measurement target in a single measurement by the film thickness sensor, the first film thickness data measured at a first measurement point on the polishing object, and the second film thickness data measured at a second measurement point on the polishing object. A distance between the first measurement point and the second measurement point is equal to or less than the size of the measurement range.

In this embodiment, the corrector obtains the corrected film thickness data based on the size of the measurement range on the polishing object as the measurement target in the single measurement by the film thickness sensor, the first film thickness data measured at the first measurement point on the polishing object, and the second film thickness data measured at the second measurement point on the polishing object. In particular, since the size of the measurement range is used for the correction, it is possible to provide the film thickness signal processing apparatus that improves the accuracy of the film-thickness distribution within the measurement range.

In a second embodiment, which is in the film thickness signal processing apparatus according to the first embodiment, a first distance from the first measurement point to a center of the polishing object and a second distance from the second measurement point to the center of the polishing object are different.

In a third embodiment, which is in the film thickness signal processing apparatus according to the first or second embodiment, the second film thickness data is measured in a first measurement after the first film thickness data is measured.

In a fourth embodiment, which is in the film thickness signal processing apparatus according to any one of the first to third embodiment, the corrector obtains at least one of third film thickness data and fourth film thickness data corresponding to third measurement point and fourth measurement point that are apart by a distance of the size on the polishing object, as the film thickness data corrected based on the first film thickness data and the second film thickness data.

In a fifth embodiment, which is in the film thickness signal processing apparatus according to the fifth embodiment, a difference between the third film thickness data and the fourth film thickness data is proportional to a difference between the first film thickness data and the second film thickness data.

In a sixth embodiment, which is in the film thickness signal processing apparatus according to any one of the first to fifth embodiment, the correction is performed when a change amount in time of the first film thickness data or the second film thickness data exceeds a predetermined value.

In a seventh embodiment, which is in the film thickness signal processing apparatus according to any one of the first to sixth embodiment, the correction is performed when a change amount in position of the first film thickness data or the second film thickness data exceeds a predetermined value.

In an eighth embodiment, which is in the film thickness signal processing apparatus according to any one of the first to seventh embodiment, the correction is performed based on the first film thickness data and the second film thickness data measured in a vicinity of an end of the polishing object.

In a ninth embodiment, which is in the film thickness signal processing apparatus according to the eighth embodiment, the correction is performed when the end is within the measurement range of the film thickness sensor.

In a tenth embodiment, which is in the film thickness signal processing apparatus according to any one of the first to ninth embodiment, the size is a first size when a distance between the polishing object and the film thickness sensor is a first length, the size is a second size when a distance between the polishing object and the film thickness sensor is a second length, and when the first length is longer than the second length, the first size is larger than the second size.

In an eleventh embodiment, a polishing apparatus includes a polishing table, a driver, a holder, a film thickness sensor, and the film thickness signal processing apparatus according to any one of the first to tenth embodiments. A polishing pad for polishing the polishing object is attachable to the polishing table. The driver is configured to rotatably drive the polishing table. The holder is configured to hold and press the polishing object against the polishing pad. The film thickness sensor is arranged in a hole formed in the polishing table and configured to detect a film thickness of the polishing object as the polishing table rotates.

In a twelfth embodiment, a film thickness signal processing method uses a polishing apparatus including a film thickness sensor, a receiver, and a corrector. The film thickness signal processing method includes: receiving sensor data output from the film thickness sensor to detect a film thickness of a polishing object by the receiver and generating first film thickness data and second film thickness data; correcting the first film thickness data and the second film thickness data generated by the receiver by the corrector; obtaining the corrected film thickness data based on a size of a measurement range as a measurement target in a single measurement by the film thickness sensor, the first film thickness data measured at a first measurement point on the polishing object, and the second film thickness data measured at a second measurement point on the polishing object by the corrector. A distance between the first measurement point and the second measurement point is equal to or less than the size of the measurement range.

### BRIEF DESCRIPTION OF DRAWINGS

FIG. 1 is a schematic diagram illustrating an overall configuration of a polishing apparatus;

FIG. 2 is a schematic diagram illustrating an example of a configuration of an eddy current sensor in this embodiment;

FIG. 3 is a diagram illustrating an actual film-thickness distribution and a film-thickness distribution obtained using the eddy current sensor;

FIG. 4 is a diagram illustrating a film-thickness distribution obtained by executing a correction according to Japanese Patent No. 6795337;

FIGS. 5A and 5B are diagrams illustrating the correction according to Japanese Patent No. 6795337;

FIGS. 6A and 6B illustrate the eddy current sensor arranged on a polishing table rotating as the polishing table rotates;

FIG. 7 illustrates a trajectory of the eddy current sensor on the polishing object as the eddy current sensor passes over a surface of the polishing object;

FIG. 8 is a diagram for describing how to obtain fourth film thickness data;

FIG. 9 illustrates an example of selecting a range in a predetermined distance from an end as a vicinity based on past measured values or prior test data;

FIG. 10 is a flowchart for describing a correction method;

FIGS. 11A and 11B are diagrams for describing how to set an outer shape size of a measurement range;

FIGS. 12A and 12B are diagrams for describing how to set the outer shape size of the measurement range; and

FIGS. 13A, 13B, and 13C are diagrams for describing how to set the outer shape size of the measurement range.

### DESCRIPTION OF EMBODIMENTS

The following is a description of the embodiments of this invention, with reference to the drawings. In the following embodiments, the same or equivalent parts may be given the same symbol to omit repeated explanations. The features illustrated in each embodiment are also applicable to other embodiments, as long as they do not contradict each other.

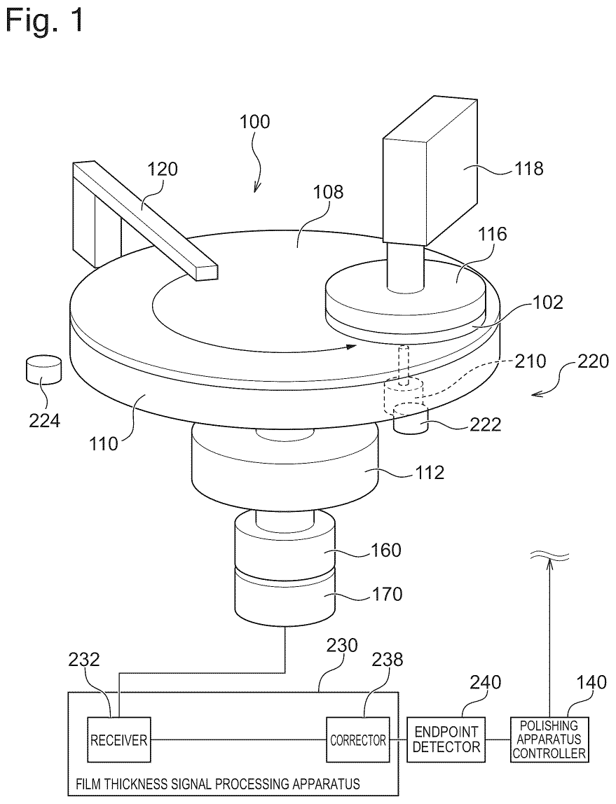

FIG. 1 is a schematic diagram illustrating an overall configuration of a polishing apparatus of one embodiment. As illustrated in FIG. 1, a polishing apparatus 100 includes a polishing table 110 in which a polishing pad 108 for polishing a polishing object (for example, a substrate such as a semiconductor wafer or various films formed on the surface of the substrate) 102 can be attached to a top surface of the polishing table 110, a first electric motor (driver) 112 that rotatably drives the polishing table 110, a top ring (holder) 116 configured to hold the polishing object 102 and press it against the polishing pad, and a second electric motor (driver) 118 that rotatably drives the top ring 116.

In addition, the polishing apparatus 100 includes a slurry line 120 that supplies a polishing fluid containing abrasive material to a top surface of the polishing pad 108. The polishing apparatus 100 includes a polishing apparatus controller 140 that outputs various control signals related to the polishing apparatus 100.

The polishing apparatus 100 includes an eddy current sensor 210 (film thickness sensor) that is arranged in a hole formed in the polishing table 110 and detects the film thickness of the polishing object 102 along the polishing surface as the polishing table 110 rotates. The polishing apparatus 100 also includes a trigger sensor 220 that includes a proximity sensor 222 arranged on the polishing table 110 and a dog 224 arranged outside the polishing table 110.

The eddy current sensor 210 includes an excitation coil, a detection coil, and a balance coil. The excitation coil is excited by an alternating current supplied from an AC power source, and forms an eddy current in the polishing object 102 arranged in a vicinity. The magnetic flux generated by the eddy current formed in the polishing object 102 is coupled to the detection coil and the balance coil. Since the detection coil is arranged in a position closer to a conductive film, a balance of the induced voltage generated in both coils is disrupted. As a result, the eddy current sensor 210 detects a linked magnetic flux formed by the eddy currents in the polishing object, and detects the thickness of the polishing object based on the detected linked magnetic flux. In this example, the eddy current sensor 210 is arranged, but it is not limited thereto, and an optical sensor that detects the thickness of the polishing object by irradiating light on the polishing object and measuring the interference wave reflected from the polishing object may be arranged.

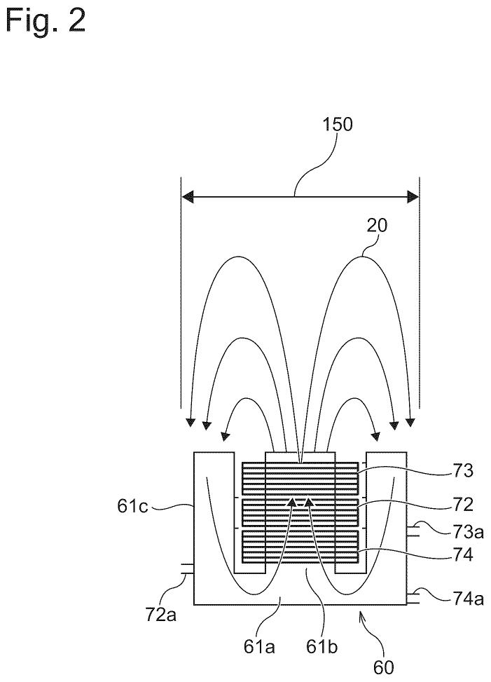

FIG. 2 is a schematic diagram illustrating an example of a configuration of the eddy current sensor 210 of this embodiment. As illustrated in FIG. 2, the eddy current sensor 210 is constituted of a pot core 60 and three coils 72, 73, and 74. The pot core 60, which is a magnetic material, has a bottom surface portion 61a, a magnetic core portion 61b provided in a center of the bottom surface portion 61a, and a peripheral wall portion 61c provided around the bottom surface portion 61a.

Among the three coils 72, 73 and 74, the central coil 72 is an excitation coil connected to an AC signal source (not illustrated). The excitation coil 72 forms the eddy currents in the metal film (or the conductive film) on the polishing object 102 arranged in the vicinity, due to the magnetic field formed by the voltage supplied from the AC signal source. The detection coil 73 is arranged on the metal film side of the excitation coil 72, and detects the magnetic field generated by the eddy currents formed in the metal film. The balance coil 74 is arranged on the opposite side of the detection coil 73 across the excitation coil 72. The balance coil 74 is a resistance bridge circuit (not illustrated) used to detect the magnetic field generated by the eddy current, and is used to adjust the balance. The balance coil 74 is configured to detect the zero point. Therefore, it is possible to detect the eddy currents flowing in the metal film from a zero state, and the detection sensitivity of the eddy currents in the metal film is increased. The excitation coil 72 is arranged in the magnetic core portion 61b and forms the eddy currents in the metal film. The detection coil 73 is arranged in the magnetic core portion 61b and detects the eddy currents formed in the metal film. Compared with the conventional eddy current sensors that use solenoid coils, the eddy current sensor 210 has a magnetic flux 20 that is concentrated and has a narrow spread.

When the film thickness of the metal film changes, the eddy currents change, and the impedances of the detection coil 73 and the balance coil 74 change. The eddy current sensor 210 of this embodiment detects changes in the film thickness of the metal film from the changes in the impedance. The receiver 232 detects the impedance from the sensor data output by the eddy current sensor 210. When the impedance changes, it is possible to detect the change in the film thickness of the metal film.

The receiver 232 receives the sensor data (for example, voltage signal) output from the film thickness sensor and detects the impedance from the sensor data. The receiver 232 calculates a difference between the detected impedance and the impedance when the film thickness is “0”, and outputs the difference as the film thickness data. The impedance when the film thickness is “0” is measured in advance. The reason for calculating the difference is to allow that the film thickness data is “0” when the film thickness is “0”.

The film thickness data is not limited to the differences in impedance. For example, a relationship between the impedance and the actual film thickness may be measured in advance before the polishing, and the receiver 232 may use the relationship to calculate the film thickness from the detected impedance during the polishing, and use the calculated film thickness as the film thickness data. In the embodiment of the present invention described below, the film thickness is calculated from the detected impedance, and the calculated film thickness is used as the film thickness data. In addition, a quantity other than the impedance that depends on the film thickness can be used to generate the film thickness data. The eddy current sensor 210 is not limited to the pot-shaped core illustrated in FIG. 2. For example, a solenoid coil, an E-shaped core, or a U-shaped core can be used.

The proximity sensor 222 is attached to the bottom surface (the side to which the polishing pad 108 is not attached) of the polishing table 110. The dog 224 is arranged on the outside of the polishing table 110 such that it can be detected by the proximity sensor 222. The trigger sensor 220 outputs a trigger signal indicating that the polishing table 110 has rotated one time based on the relative positions of the proximity sensor 222 and the dog 224. Specifically, the trigger sensor 220 outputs a trigger signal when the proximity sensor 222 and the dog 224 are closest to each other.

The eddy current sensor 210 controls a timing of start and a timing of end of the measurement based on the trigger signal output from the trigger sensor 220. For example, the eddy current sensor 210 sets a timing at which a predetermined time has elapsed since the trigger signal was output from the trigger sensor 220 as a timing at which the measurement starts, and sets a timing at which a predetermined time has elapsed since the trigger signal was output from the trigger sensor 220 as a timing at which the measurement ends. Here, the predetermined time is set as a parameter in advance.

When polishing the polishing object 102, the polishing apparatus 100 supplies a polishing slurry containing polishing abrasive grains from the slurry line 120 to the top surface of the polishing pad 108, and rotatably drives the polishing table 110 with the first electric motor 112. The polishing apparatus 100 then presses the polishing object 102 held in the top ring 116 against the polishing pad 108 while rotating the top ring 116 about a rotation axis that is offset from the rotation axis of the polishing table 110. This causes the polishing object 102 to be polished and flattened by the polishing pad 108, which holds the polishing slurry.

Next, a film thickness signal processing apparatus 230 of this embodiment is described. As illustrated in FIG. 1, the film thickness signal processing apparatus 230 is connected to the eddy current sensor 210 via rotary joint connectors 160, 170. The film thickness signal processing apparatus 230 performs a predetermined signal processing on the sensor data output from the eddy current sensor 210 and outputs it to an endpoint detector 240.

The endpoint detector 240 monitors changes in the film thickness of the polishing object 102 based on the signal output from the film thickness signal processing apparatus 230. The endpoint detector 240 is connected to the polishing apparatus controller 140, which performs various controls related to the polishing apparatus 100. When the endpoint detector 240 detects the end of polishing of the polishing object 102, it outputs a signal indicating this to the polishing apparatus controller 140. When the polishing apparatus controller 140 receives the signal indicating that the polishing process has ended from the endpoint detector 240, it stops the polishing process using the polishing apparatus 100. During the polishing, the polishing apparatus controller 140 controls the pressing force of the polishing object 102 based on the corrected film thickness data.

Here, the problem of the conventional technology is described. In the polishing process of semiconductor wafers, the shape control of the film thickness and the film-thickness distribution during the polishing is considered to be very important. It is common practice to perform in-situ film-thickness measurement (that is, film-thickness measurement during polishing) using an eddy current sensor or an optical sensor, and to perform pressure control using the top ring 116 based on the measurement results. In the past, when the sensor is positioned close to the end of the wafer, and an area outside the wafer (that is, the area outside the end of the wafer) is included within the measurement range of the sensor, there was a problem with the inability to accurately estimate the shape of the film-thickness distribution. Also, in the past, the sensor output is thought to be measuring the average film thickness within the measurement range of the sensor. Therefore, when there are irregularities in the film thickness within an area smaller than the outer shape size of the measurement range of the sensor, these irregularities cannot be detected. As a result, there was a problem with being unable to accurately estimate the shape of the film-thickness distribution.

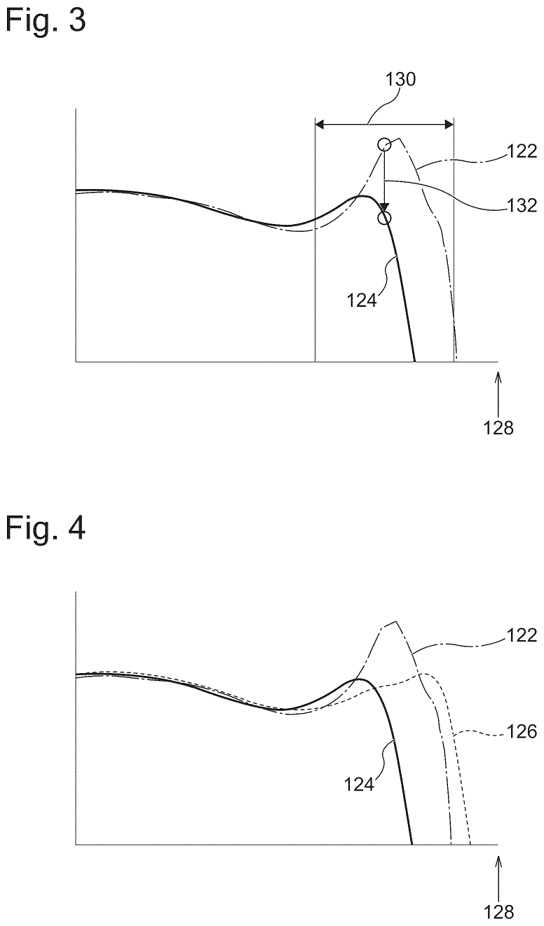

This will be described further in FIGS. 3 and 4. FIG. 3 illustrates an actual film-thickness distribution 122 and a film-thickness distribution 124 obtained using the eddy current sensor 210. The film-thickness distribution 124 has not been corrected. FIG. 4 also illustrates a film-thickness distribution 126 obtained by correcting the data according to Japanese Patent No. 6795337. The horizontal axis of the graph indicates the distance (unit:mm) from the center of the circular polishing object 102 (wafer). However, this is a film-thickness distribution only in the vicinity of an end 128. Therefore, the center of the polishing object 102 is present in the left beyond the left end of the graph. The vertical axis is the film thickness (unit:angstroms). However, in order to indicate the change in the film thickness in the vicinity of the end 128 where the film thickness of the polishing object 102 has the maximum value in detail, the film thickness in the region where the film thickness is small (that is, the end 128) is not illustrated so as to allow the vertical axis to include the maximum value of the film thickness. In other words, the minimum value of the vertical axis illustrated in FIGS. 3 and 4 is greater than 0angstroms. The film thickness at the end is 0 angstroms because there is no metal film outside the end.

In FIG. 3, a difference 132 between the actual film-thickness distribution 122 and the film-thickness distribution 124 obtained by the eddy current sensor 210 is quite large within an outer shape size 130 of the measurement range of the eddy current sensor 210. The difference 132 outside the end decreases toward the center of the polishing object 102. Conventionally, the measured film thickness (the film thickness before correction) indicated by the film-thickness distribution 124 is the average of the actual film thickness within the outer shape size 130, and the accuracy of the average is low. The accurate film-thickness distribution 122 could not be measured in the past. FIG. 4 illustrates the film-thickness distribution 126 using the conventional correction method.

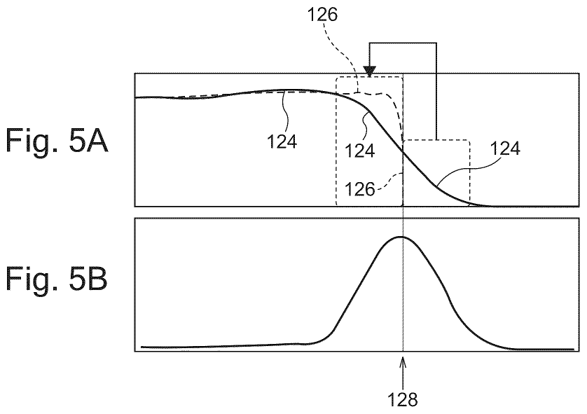

The method for obtaining the film-thickness distribution 126 is described using FIGS. 5A and 5B. FIG. 5A illustrates the film-thickness distribution 124 obtained using the eddy current sensor 210 and the film-thickness distribution 126 obtained by correcting it according to Japanese Patent No. 6795337. The horizontal axis of the figure is the distance (unit:mm) from the center of the circular polishing object 102. However, this is the film-thickness distribution only in the vicinity of the end 128. Therefore, the center of the polishing object 102 is in the left beyond the left end of the figure. The vertical axis is the film thickness (unit:angstrom). Outside the end 128, the film-thickness distribution 124 is 0 angstroms. The actual film thickness is 0 angstroms at the end 128.

FIG. 5B is a graph illustrating the film-thickness distribution 124 differentiated by distance from the center of the polishing object 102. The horizontal axis of the graph is the distance (unit:mm) from the center of the circular polishing object 102. The vertical axis of the graph is the differential value (unit:angstroms/mm). In the correction according to Japanese Patent No. 6795337, it is first assumed that the end 128 of the polishing object 102 is at the peak position of the differential value. Then, for the correction, a value of the film-thickness distribution 124 at a position by a distance x from the end 128 to an outside of the polishing object 102 is added to a value of the film-thickness distribution 124 at a position by the distance x from the end 128 to an inside of the polishing object 102. In this way, the film-thickness distribution 126 is obtained. The film-thickness distribution 126 then rapidly decreases in value at the end 128 to 0 angstroms. Returning to FIG. 4, when the film-thickness distribution 122 and the film-thickness distribution 126 are compared, the corrected film thickness in the vicinity of the end differs greatly from the actual film thickness in the conventional correction method. The correction illustrated in FIGS. 4 and 5 is only corrections for cases where the measurement range of the eddy current sensor 210 includes the outside of the end of the polishing object 102. Because it uses a signal that has been averaged within the measurement range of the eddy current sensor 210, it is not possible to take into account the local film-thickness distribution within the measurement range of the eddy current sensor 210.

On the other hand, in one embodiment of the present invention, the size of the measurement range is used for the correction, so it is possible to provide the film thickness signal processing apparatus that improves the accuracy of the film-thickness distribution within the measurement spot, that is, the spatial resolution. In addition, the following effects are achieved. Namely, the measurement accuracy close to the end 128 (bevel) region of the polishing object 102 improves. When the eddy current sensor 210 approaches close to the end 128 of the polishing object 102 during the measurement, since a part of the magnetic flux from the eddy current sensor no longer crosses with the polishing object 102, the shape of the measurement range changes, and/or the outer shape of the measurement range becomes smaller than before it approaches close to the end 128. Therefore, it is difficult for the output from the eddy current sensor 210 to be stable. According to one embodiment of the present invention, the measurement accuracy close to the end improves.

The film thickness signal processing apparatus 230 of the one embodiment of the present invention includes a receiver 232 and a corrector 238. The receiver 232 receives the sensor data output from the eddy current sensor 210 (the film thickness sensor) to detect the film thickness of the polishing object 102, and generates first film thickness data and second film thickness data. The corrector 238 corrects the first and second film thickness data generated by the receiver 232.

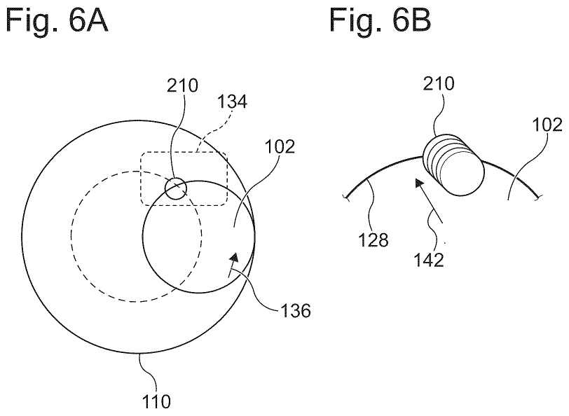

The correcting method of the corrector 238 is described using FIGS. 6A, 6B, 7, and 8. FIG. 6A illustrates the eddy current sensor 210 arranged on the polishing table 110 rotating as the polishing table 110 rotates. An arrow 136 indicates the direction of rotation of the polishing table 110. FIG. 6B is a magnified view of an area 134 illustrated in FIG. 6A. In FIGS. 6A and 6B, the eddy current sensor 210 is moving from an inside to an outside of the polishing object 102, and the eddy current sensor 210 is positioned in the vicinity of the end 128 of the polishing object 102. The eddy current sensor 210 is moving in the direction indicated by an arrow 142 with respect to the polishing object 102. The reason why there are a plurality of the eddy current sensors 210 represented is to indicate the position of each of the measurement points of the eddy current sensor 210.

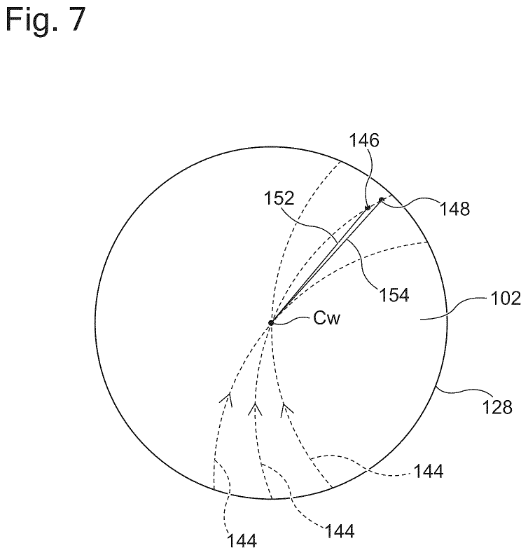

FIG. 7 illustrates a trajectory 144 on the polishing object 102 when the eddy current sensor 210 passes over the surface of the polishing object 102. This diagram indicates three example trajectories 144. In the actual measurement, the number of trajectories 144 is more than three, and they are distributed over the entire polishing object 102. The position and number of trajectories can be set arbitrarily. The arrow on the trajectory 144 indicates the direction of movement of the eddy current sensor 210. In this figure, the trajectory 144 passes through a center Cw of the polishing object 102. The trajectory 144 does not have to pass through the center Cw. The measurement points such as the first measurement point 146 and the second measurement point 148 are present on the trajectory 144.

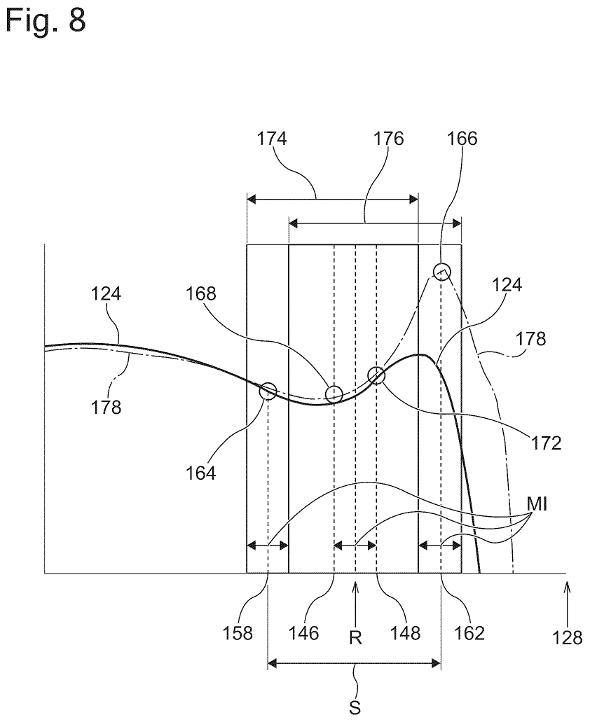

As illustrated in FIG. 8, the corrector 238 obtains third film thickness data 164 or fourth film thickness data 166 corrected based on a size of a measurement range 150 on the polishing object 102 as a measurement target in a single measurement by the eddy current sensor 210, first film thickness data 168 measured at the first measurement point 146 on the polishing object, and second film thickness data 172 measured at the second measurement point 148 on the polishing object 102. The distance between the first measurement point 146 and the second measurement point 148 is equal to or less than the outer shape size 130 of the measurement range 150. Here, the single measurement refers to a measurement at each of the first measurement point 146, the second measurement point 148, and the like on the single trajectory 144 illustrated in FIG. 7. Details of FIG. 8 will be described later.

In FIG. 7, the next measurement after the measurement at the first measurement point 146 is performed at the second measurement point 148. In other words, the second film thickness data is measured in the first measurement after the first film thickness data is measured. For example, the n-th measurement is performed at the first measurement point 146, and the (n+1)-th measurement is performed at the second measurement point 148. The first measurement point 146 and the second measurement point 148 do not have to be consecutive measurement points, and there may be another measurement point between the first measurement point 146 and the second measurement point 148.

In the case of the eddy current sensor, the measurement range 150 of the eddy current sensor 210 is the measurement range on the polishing object 102 where the induced eddy current is present, and in the case of an optical sensor, it is the light irradiation range on the polishing object 102. In the case of the eddy current sensor, the measurement range depends on the shape of the core and the shape of the coil (coil winding method, arrangement, the number of windings, and the like.). The eddy current sensor 210 illustrated in FIG. 2 is the pot core 60. In the case of FIG. 2, the outer shape of the measurement range 150 is circular. The outer shape of the measurement range 150 (or the diameter of the circle in the case of a circle) is almost the same as the outer shape of the pot core 60, but it is slightly larger than the pot core 60. In some cases, the outer shape size 130 of the measurement range 150 is smaller than the outer shape of the pot core 60. When the core is an E-shaped core, the measurement range is elliptical. An example is discussed later how to determine the outer shape size of the measurement range 150, including the case of an elliptical shape. In the case of the optical sensor, the outer shape size of the measurement range may be larger or smaller than the outer diameter (diameter of the circle) of the optical fiber that emits light.

As illustrated in FIG. 7, a first distance 152 from the first measurement point 146 to the center Cw of the polishing object 102 is different from a second distance 154 from the second measurement point 148 to the center Cw of the polishing object 102. The second distance 154 is greater than the first distance 152. To put it another way, the second measurement point 148 is closer to the end 128 of the polishing object 102 than the first measurement point 146.

As illustrated in FIG. 8, the corrector obtains one of the third film thickness data 164 and the fourth film thickness data 166 corresponding to a third measurement point 158 and a fourth measurement point 162, which are separated by a distance of the outer shape size 130 of the measurement range 150 on the polishing object 102, based on the first film thickness data 168 and the second film thickness data 172, as described later. In this figure, the fourth film thickness data 166 is obtained as the fourth film thickness data 166 that has been corrected based on the first film thickness data 168 and the second film thickness data 172. The difference between the third film thickness data 164 and the fourth film thickness data 166 is proportional to the difference between the first film thickness data 168 and the second film thickness data 172, as described later.

The method for obtaining the fourth film thickness data 166 is described with reference to FIG. 8. FIG. 8 is a diagram for describing the method for obtaining the fourth film thickness data 166. The horizontal axis in FIG. 8 is the distance (unit: mm) from the center of the circular polishing object 102. However, this is the film-thickness distribution only in the vicinity of the end 128. The center of the polishing object 102 is in the left beyond the left end of the diagram. The vertical axis is the film thickness (unit: angstroms). However, in order to indicate the change in the film thickness in the vicinity where the film thickness of the polishing object 102 has the maximum value in detail, the vertical axis in the region where the film thickness is small (that is, the end) is not illustrated so as to allow the vertical axis to include the maximum value of the film thickness. In other words, the minimum value of the vertical axis illustrated in FIG. 8 is greater than 0 angstroms.

As illustrated in FIG. 8, the first measurement point 146 and the second measurement point 148 are separated by a distance MI. The third measurement point 158 and the fourth measurement point 162 are separated by a distance S (that is, the outer shape size 130). The measurement range 150 of the eddy current sensor 210 when the eddy current sensor 210 is positioned at the first measurement point 146 is indicated by an arrow 174. The first measurement point 146 is positioned at the center of the arrow 174. The measurement range 150 of the eddy current sensor 210 when the eddy current sensor 210 is positioned at the second measurement point 148 is indicated by an arrow 176. The second measurement point 148 is positioned at the center of the arrow 176.

The position R is defined as a midpoint between the first measurement point 146 and the second measurement point 148, the third measurement point 158 is in a position from the position R toward the center Cw by a half of the distance S. The fourth measurement point 162 is in a position from the position R toward the end 128 by a half of the distance S.
In this case, the first film thickness data 168 is Tmoni (R−MI/2),
the second film thickness data 172 is Tmoni (R+MI/2),
the third film thickness data 164 is TAct (R−S/2), and
the fourth film thickness data 166 is TAct (R+S/2).
   In addition, the average value of the film thickness data in the measurement range 150 using the eddy current sensor 210 is defined as Toverlapped. The average value of the film thickness data Toverlapped is considered to be approximately the same in the range where the range of the arrow 174 and the range of the arrow 176 overlap.

In this case, the first film thickness data 168={the average value of the film thickness data Toverlapped×(the outer shape size−(the distance MI between the measurement point 146 and the second measurement point 148))+the third film thickness data 164×(the distance MI between the first measurement point 146 and the second measurement point 148)}/the outer shape size (1).

In other words, the first film thickness data 168 is considered to be the weighted average of the average value of the film thickness data Toverlapped and the third film thickness data 164, using the lengths (S−MI) and (MI).

When Formula (1) is expressed using only the already used symbols, Tmoni (R−MI/2)={Toverlapped×(S−MI)+TAct (R−S/2)×MI}/S (2)

is obtained.

Similarly, for the second film thickness data 172, the second film thickness data 172={the average value of the film thickness data Toverlapped×(the outer shape size−(the distance MI between the first measurement point 146 and the second measurement point 148))+the fourth film thickness data 166×(the distance MI between the measurement point 146 and the second measurement point 148)}/the outer shape size (3).

In other words, the second film thickness data 172 is considered to be the weighted average of the average value of the film thickness data Toverlapped and the fourth film thickness data 166, using the lengths (S−MI) and (MI). When Formula (3) is expressed using only the already used symbols, Tmoni (R+MI/2)={Toverlapped×(S−MI)+TAct (R+S/2)×MI}/S (4)

is obtained.

When Formula (2) is subtracted from Formula (4) and multiply both sides by (S/MI), TAct (R+S/2)−TAct (R−S/2)=(Tmoni (R+MI/2)−Tmoni (R−MI/2))×(S/MI) (5)

is obtained. In other words, the first film thickness data 168 and the second film thickness data 172 can be used to obtain the fourth film thickness data 166. The obtained fourth film thickness data 166 is a film-thickness distribution 178. When the film-thickness distribution 178 is compared with the film-thickness distribution 126 corrected using the conventional technology illustrated in FIG. 4, it is found that it has been considerably improved and is now closer to the actual film-thickness distribution 122.

Formula (5) is an expression that represents the difference between the third film thickness data 164 and the fourth film thickness data 166. Therefore, when starting to correct using Formula (5), as described later, it is necessary to specify the third film thickness data 164 as the initial value. The method for setting the initial value is described later. According to Formula (5), the difference in the film thickness between two points separated by the distance S can be calculated from the difference in monitor values between the consecutive measurement points. The conventional measurement values are the first film thickness data 168 and the second film thickness data 172, which can be considered to be the average film thickness values across the entire measurement range 150. In other words, the spatial resolution of the conventional film thickness measurement is the distance S (the size of the entire measurement range 150). On the other hand, according to Formula (5), the film thickness in the distance MI section can be obtained. Therefore, the measurement spatial resolution can be improved from S to MI.

In Formula (5), the first film thickness data 168 and the second film thickness data 172 are adjacent measurement values, but in Formula (5), it is also possible to use measurement values that are not adjacent. Also, although the expressions “third measurement point 158” and “fourth measurement point 162” are used, this does not mean that the third measurement point 158 and the fourth measurement point 162 are the positions where the eddy current sensor 210 actually performs the measurements. The third measurement point 158 and the fourth measurement point 162 are the positions where the film thickness data is measured by the correction.

When starting the correction using Formula (5), it is necessary to specify the third film thickness data 164 as the initial value. The method for setting the initial value is described below. The first film thickness data 168 at the point where the correction is to start can be used as the initial value for the third film thickness data 164. The point where the correction is to start can be selected in various ways, as follows. The correction is started when the change amount of time in the first film thickness data 168 or the second film thickness data 172 exceeds a predetermined value, and is performed for a predetermined period. The predetermined period is, for example, until the end 128 is reached. Alternatively, the correction is performed when the change amount in position in the first film thickness data 168 or the second film thickness data 172 exceeds a predetermined value.

Such increases in the change amount often occur in the vicinity of the end 128. Therefore, it is preferred to correct based on the first film thickness data 168 and the second film thickness data measured at the end 128, by performing the correction only in the vicinity of the end 128 of the polishing object 102. As the vicinity, a range at a predetermined distance from the end can be selected based on the past measured values or the prior test data. Furthermore, the correction may be performed when the end 128 of the polishing object 102 is within the measurement range 150 of the eddy current sensor 210.

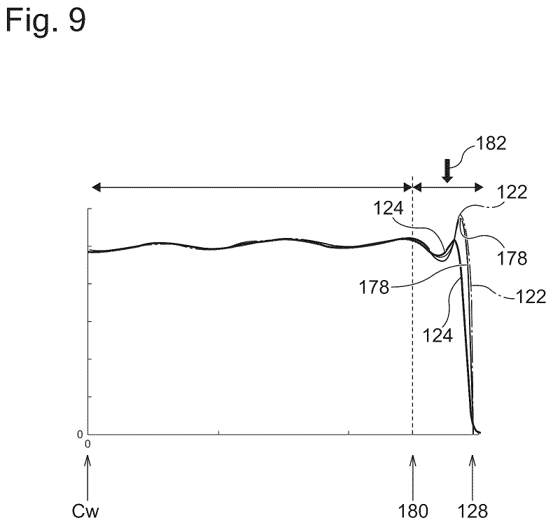

FIG. 9 illustrates an example of selecting a range that is a predetermined distance from the end as the vicinity, based on the past measured values or the prior test data. The horizontal axis of the figure is the distance (unit:mm) from the center of the circular polishing object 102. The vertical axis is the film thickness (unit:angstroms). This figure illustrates the actual film-thickness distribution 122, the film-thickness distribution 124 as the values measured by the eddy current sensor 210, and the film-thickness distribution 178 illustrated in FIG. 8 obtained by correcting the data according to one embodiment of the present application. The actual film-thickness distribution 122 is a measurement taken by a different and a more accurate film-thickness measurement device than the eddy current sensor 210. FIG. 9 illustrates a position 180 where the correction is started. The correction related to one embodiment of the present application is performed in the region indicated by an arrow 182 from the position 180 to the end 128. The range to be corrected is predetermined in advance, and the correction is performed from the inside of the polishing object 102 toward the end 128.

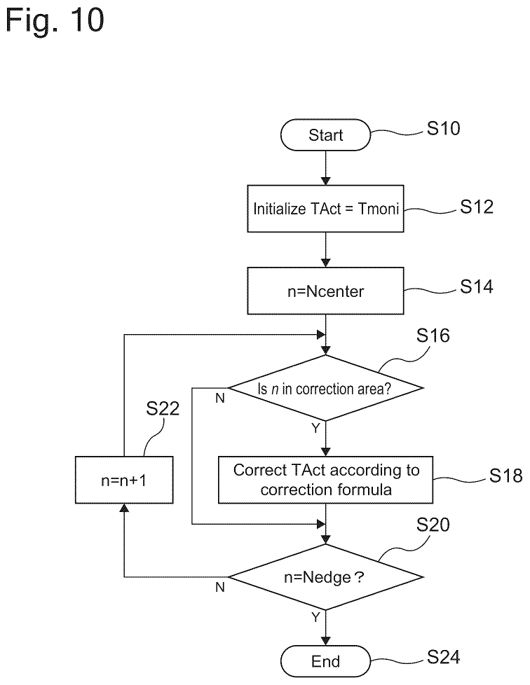

The flowchart in FIG. 10 is used to describe the correction method. In FIG. 10, the case where the measurement and the correction are performed when moving from the center Cw to the end 128 of the polishing object 102 is described. Note that the correction may also be performed on the film thickness data obtained when moving from the end 128 to the center Cw. For example, after the eddy current sensor 210 has passed under the polishing object 102 (one scan), before the next scan, the correction can be applied in order from the inside to the end 128 of the polishing object 102 in the film thickness data indicating the obtained film-thickness distribution. In this way, the film thickness data obtained when moving from the end 128 to the center Cw of the polishing object 102 can also be corrected. In this embodiment, the order of applying the correction to the film thickness data is from the center Cw to the end 128. In other words, the film thickness data at the measurement points on the inside of the polishing object 102 is used to correct the film thickness data at the measurement points on the outside. Note that, in locations other than the vicinity of the end 128, the order of applying the correction to the film thickness data may be from the end 128 to the center Cw. A continuous number is assigned in advance to each measurement point of the trajectory 144 illustrated in FIG. 7, from the time the eddy current sensor 210 enters the polishing object 102 at the end 128 to the time the eddy current sensor 210 exits the polishing object 102 at the end 128. The number of the center Cw is Ncenter. The correction is started from the center Cw (S10).

At first, in order to initialize the above-described value of TAct (R−S/2) as the initialization of the data (S12), the measured value (Tmoni) obtained at the center Cw is substituted into TAct (R−S/2). In other words, TAct=Tmoni. The operation of setting TAct=Tmoni is performed in S22, which is described later, until the measurement point where TAct (R+S/2) is obtained by calculation according to Formula (5) is reached after entering the correction area. After the measurement point where TAct (R+S/2) has been obtained by calculation is reached, the operation of setting TAct=Tmoni is not necessary because TAct has been obtained by the calculation. As illustrated in FIG. 8, the position where TAct (R−S/2) is set is away from the measurement point where Tmoni (R−MI/2) is measured by S/2−MI/2.Tmoni is not necessarily and precisely present at the position where TAct (R−S/2) is set. When it is not present, Tmoni closest to the position may be used.

The value Ncenter is entered into a counter n, which indicates the position of the measurement point (S14). Next, the value of the counter n is determined to see whether or not it is within the correction area indicated by the arrow 182 in FIG. 9 (S16). The number ns, which indicates the position 180 where the correction starts, is set in advance, and when the value of the counter n is equal to or greater than number ns, it is determined to be in the correction area (when Yes at S16). When the value of the counter n is less than number ns, it is determined that the area is not in the correction area (in the case of No in S16). When it is in the correction area, TAct (R+S/2) is calculated according to Formula (5) and corrected (S18). Next, it is determined whether it is n=Nedge, which indicates the end 128 of FIG. 9 based on the value of the counter n (S20). When it has been reached (when Yes), the correction is finished (S24). When it has not been reached (when No), the value of the counter n, which indicates the position of the measurement point, is increased by one, and the film thickness is measured (S22). Then, the process proceeds to S16. When it is determined that the value of the counter n is less than number ns and that it is not in the correction area (when No at S16) at S16, the process proceeds to S20.

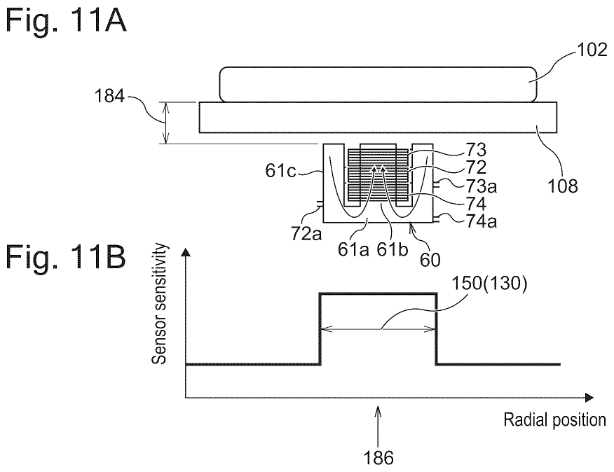

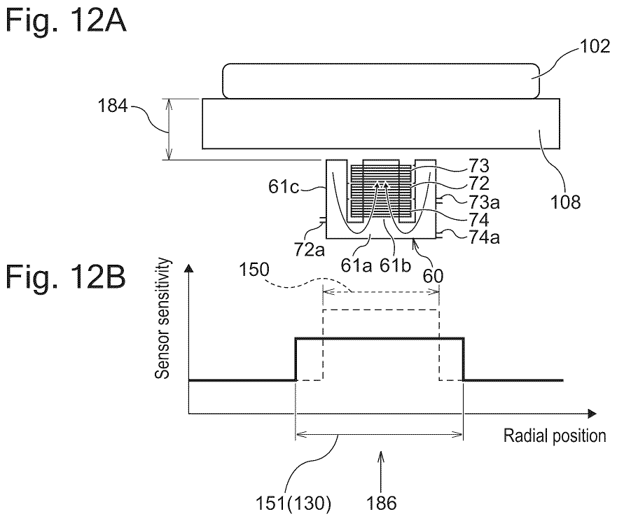

Next, it is described how to set the outer shape size 130 of the measurement range 150 (that is, the distance S) using FIGS. 11A to 13C. The measurement range 150 (the range in which the eddy current sensor 210 reacts) changes depending on a distance 184 (see FIGS. 11A and 12A) between the eddy current sensor 210 and the polishing object 102. When the distance 184 increases, the sensitivity of the eddy current sensor 210 decreases and the measurement range 150 increases. FIG. 11B illustrates the sensitivity of the eddy current sensor 210 and the measurement range 150 when the distance 184 is narrow. FIG. 12B illustrates the sensitivity and a measurement range 151 of the eddy current sensor 210 when the distance 184 is wide. The horizontal axes in FIGS. 11B and 12B illustrate the radial position (unit:mm) from a center 186 of the eddy current sensor 210. The vertical axes in FIGS. 11B and 12B indicate the sensitivity (unit:mV) at each radial position from the center 186 of the eddy current sensor 210. Sensitivity is the magnitude of the output of the eddy current sensor 210.

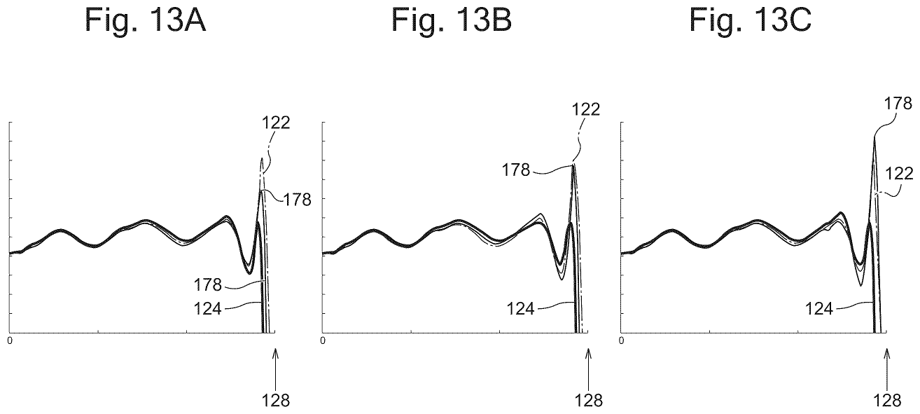

When FIGS. 11B and 12B are compared, it is found that even when the eddy current sensor 210 is the same, the appropriate outer shape size 130 differs depending on the thickness of the used polishing pad 108. Therefore, the value of the outer shape size 130 is adjusted to determine the value of the outer shape size 130 such that the film-thickness distribution 178 after the correction matches the film-thickness distribution 122 measured using a film-thickness measurement device more accurate than the eddy current sensor 210. The determined outer shape size 130 is used in Formula (5). FIGS. 13A, 13B, and 13C illustrate the film-thickness distribution 178 when the outer shape size 130 is varied.

The horizontal axis of each diagram in FIGS. 13A, 13B, and 13C is the distance (unit:mm) from the center of the circular polishing object 102. The vertical axis is the film thickness (unit:angstroms). However, in order to indicate the change in the film thickness in the vicinity where the film thickness of the polishing object 102 has the maximum value in detail, the film thickness in the region where the film thickness is small (that is, the end) is not illustrated so as to allow the vertical axis to include the maximum value of the film thickness. In other words, the minimum values on the vertical axis illustrated in FIGS. 13A, 13B, and 13C are greater than 0 angstroms. The film thickness at the end is not illustrated in the figure, but it is 0 angstroms because there is no metal film on the outside of the end. FIGS. 13A, 13B, and 13C also illustrate the film-thickness distribution 124 before the correction and the film-thickness distribution 122 measured by the film-thickness measuring instrument for comparison.

In FIG. 13B, which illustrates the film-thickness distribution 178 after the correction when using the appropriate outer shape size 130, the film-thickness distribution 178 and the film-thickness distribution 122 are most closely matched. The outer shape size 130 used in FIG. 13A is smaller than the outer shape size 130 used in FIG. 13B. The outer shape size 130 used in FIG. 13C is larger than the outer shape size 130 used in FIG. 13B. The results of FIGS. 11A to 13C can be summarized as follows. The outer shape size 130 when the distance 184 between the polishing object 102 and the eddy current sensor 210 is the first length illustrated in FIG. 12A is defined as the first size. The outer shape size 130 when the distance between the polishing object 102 and the eddy current sensor 210 is the second length illustrated in FIG. 11A is the second size. In this case, when the first length is longer than the second length, the first size is larger than the second size.

When the outer shape of the eddy current sensor 210 is a circle, the diameter of the outer shape can be used as the initial value for the size 130, and the size 130 can be determined using the method illustrated in FIGS. 13A, 13B, and 13C. It is described how to determine the outer shape size of the measurement range 150 when the outer shape of the eddy current sensor 210 is not circular. When the outer shape of the eddy current sensor 210 is square, rectangular, or the like, the measurement range 150 is different from a circular shape. When the outer shape of the measurement range 150 is considered to be elliptical, for example, the lengths of the short axis and the long axis of the ellipse are included, and the approximate lengths of the short axis and the long axis are set to the size 130, as illustrated in FIGS. 13A, 13B, and 13C, the degree of match with the film-thickness distribution measured by the film-thickness measuring instrument is examined. The length when the degree of match is good is set as the size 130.

When the outer shape of the measurement range 150 differs from a circle or ellipse, for example, the length of the long direction of the outer shape and the length of the transverse direction that is orthogonal to this are included, and the approximate lengths of the longitudinal and transverse directions are set to the size 130, and the degree of match with the film-thickness distribution measured by the film-thickness measuring instrument is examined, as illustrated in FIGS. 13A, 13B, and 13C. The length when the degree of match is good is defined as the size 130. The size 130 can also be determined by estimating it from the size 130 adopted for similar shapes in the past.

Next, the film thickness signal processing method is described. The film thickness signal processing method using a polishing apparatus including an eddy current sensor, a receiver, and a corrector receives sensor data output from the eddy current sensor 210 to detect the film thickness of the polishing object 102 using the receiver 232, and generates the first film thickness data 168 and the second film thickness data 172. The corrector 238 corrects the first film thickness data 168 and the second film thickness data 172 generated by the receiver 232. The corrector 238 obtains the third film thickness data 164 or the fourth film thickness data 166 corrected based on the size 130 of the measurement range 150 as a measurement target in a single measurement by the eddy current sensor 210, the first film thickness data 168 measured at the first measurement point 146 on the polishing object 102, and the second film thickness data 172 measured at the second measurement point 148 on the polishing object 102. The distance between the first measurement point 146 and the second measurement point 148 is equal to or less than the outer shape size 130 of the measurement range 150.

The polishing apparatus 100 includes the polishing apparatus controller 140 that controls the overall operation of the polishing apparatus 100. The polishing apparatus controller 140 and the film thickness signal processing apparatus 230 include a CPU, a memory, a storage media, and the like. The polishing apparatus controller 140 and the film thickness signal processing apparatus 230 may be configured as a microcomputer that uses software (programs) such as polishing recipes and/or information on machine parameters of related devices that have been input in advance to achieve the desired functions (such as correcting functions), or they may be configured as a hardware circuit that performs dedicated computing. The polishing apparatus controller 140 and the film thickness signal processing apparatus 230 may be configured as a combination of a microcomputer and a hardware circuit that performs the dedicated computing.

The above is an example of an embodiment of the present invention, but the above-mentioned embodiments of the invention are provided for the purpose of facilitating understanding of the present invention and do not limit the present invention. The present invention can be modified or improved without deviating from its original intent, and of course, the present invention includes equivalents thereof. In addition, any combination of or omission of the individual components according to the claims and specifications is possible to the extent that it can solve at least part of the above-mentioned problems or achieve at least part of the effects.

### REFERENCE SIGNS LIST

100 . . . polishing apparatus
102 . . . polishing object
108 . . . polishing pad
110 . . . polishing table
112 . . . first electric motor
122, 124, 126 . . . film-thickness distribution
128 . . . end
130 . . . size
144 . . . trajectory
146 . . . first measurement point
148 . . . second measurement point
150 . . . measurement range
152 . . . first distance
154 . . . second distance
158 . . . third measurement point
162 . . . fourth measurement point
164 . . . third film thickness data
166 . . . fourth film thickness data
168 . . . first film thickness data
172 . . . second film thickness data
210 . . . eddy current sensor
230 . . . film thickness signal processing apparatus
232 . . . receiver
238 . . . corrector

1. A film thickness signal processing apparatus comprising:
a receiver configured to receive sensor data output from a film thickness sensor to detect a film thickness of a polishing object and generate first film thickness data and second film thickness data; and
a corrector configured to correct the first and second film thickness data generated by the receiver, wherein
the corrector obtains corrected film thickness data based on a size of a measurement range on the polishing object as a measurement target in a single measurement by the film thickness sensor, the first film thickness data measured at a first measurement point on the polishing object, and the second film thickness data measured at a second measurement point on the polishing object, and
a distance between the first measurement point and the second measurement point is equal to or less than the size of the measurement range.

2. The film thickness signal processing apparatus according to claim 1, wherein
a first distance from the first measurement point to a center of the polishing object and a second distance from the second measurement point to the center of the polishing object are different.

3. The film thickness signal processing apparatus according to claim 1, wherein
the second film thickness data is measured in a first measurement after the first film thickness data is measured.

4. The film thickness signal processing apparatus according to claim 1, wherein
the corrector obtains at least one of third film thickness data and fourth film thickness data corresponding to third measurement point and fourth measurement point that are apart by a distance of the size on the polishing object, as the film thickness data corrected based on the first film thickness data and the second film thickness data.

5. The film thickness signal processing apparatus according to claim 4, wherein
a difference between the third film thickness data and the fourth film thickness data is proportional to a difference between the first film thickness data and the second film thickness data.

6. The film thickness signal processing apparatus according to claim 1, wherein
the correction is performed when a change amount in time of the first film thickness data or the second film thickness data exceeds a predetermined value.

7. The film thickness signal processing apparatus according to claim 1, wherein
the correction is performed when a change amount in position of the first film thickness data or the second film thickness data exceeds a predetermined value.

8. The film thickness signal processing apparatus according to claim 1, wherein
the correction is performed based on the first film thickness data and the second film thickness data measured in a vicinity of an end of the polishing object.

9. The film thickness signal processing apparatus according to claim 8, wherein
the correction is performed when the end is within the measurement range of the film thickness sensor.

10. The film thickness signal processing apparatus according to claim 1, wherein
the size is a first size when a distance between the polishing object and the film thickness sensor is a first length, the size is a second size when a distance between the polishing object and the film thickness sensor is a second length, and when the first length is longer than the second length, the first size is larger than the second size.

11. A polishing apparatus comprising:
a polishing table to which a polishing pad for polishing the polishing object is attachable;
a driver configured to rotatably drive the polishing table;
a holder configured to hold and press the polishing object against the polishing pad;
a film thickness sensor arranged in a hole formed in the polishing table and configured to detect a film thickness of the polishing object as the polishing table rotates; and
the film thickness signal processing apparatus according to claim 1.

12. A film thickness signal processing method using a polishing apparatus including a film thickness sensor, a receiver, and a corrector, the film thickness signal processing method comprising:
receiving sensor data output from the film thickness sensor to detect a film thickness of a polishing object by the receiver and generating first film thickness data and second film thickness data;
correcting the first film thickness data and the second film thickness data generated by the receiver by the corrector;
obtaining the corrected film thickness data based on a size of a measurement range as a measurement target in a single measurement by the film thickness sensor, the first film thickness data measured at a first measurement point on the polishing object, and the second film thickness data measured at a second measurement point on the polishing object by the corrector, wherein
a distance between the first measurement point and the second measurement point is equal to or less than the size of the measurement range.
